(19) United States
(12) Patent Application Publication
(10) Pub. No.: US 2006/0090111 A1
(43) Pub. Date: Apr. 27, 2006

(54) Circuit for recursively calculating data

(75) Inventors: Sebastien Charpentier, Mougins (FR); Yordan Tabakov, Paris (FR)

Correspondence Address: PHILIPS INTELLECTUAL PROPERTY & STANDARDS, P.O. BOX 3001, BRIARCLIFF MANOR, NY, 10510, US

(73) Assignee: koninklijke phillips electronics nv

(21) Appl. No.: 10/528,622

(22) PCT Filed: Sep. 10, 2003
(86) PCT No.: PCT/IB03/03943

§ 371 Date: Mar. 22, 2005

(30) Foreign Application Priority Data
Sep. 25, 2002 (FR) 02/11839

(51) Int. Cl. G01R 31/28

(52) U.S. Cl. 714/731

(57) ABSTRACT

The invention relates to a circuit for calculating a second data set based on a first data set calculated by at least a calculation device (31) that is capable of calculating a data in a predefined number of clock cycles. The calculation device has an input (311) and an output (312). The circuit comprises transport means (32) for routing a data of the first data set from the output to the input of said calculation device, in a number of clock cycles depending on the number of data of the first data set and on the predefined number of cycles necessary for the calculation of one data. A data advances through said transport means with each clock cycle.

### FIELD OF THE INVENTION

The present invention relates to a circuit for calculating a second data set based on a first data set calculated by at least a calculation device that is capable of calculating a data in a predefined number of clock cycles, said calculation device having an input and an output.

The invention also relates to a system for calculating intracolumn permutation elements of an interleaver, a decoding circuit comprising such a system, an electronic device and a communication network comprising such a decoding circuit.

The invention finds an application, for example, in a satellite communication system or a system implementing the UMTS (UMTS=Universal Mobile Telecommunication System) standard, such as a third generation mobile telephone.

### BACKGROUND OF THE INVENTION

Certain data processing systems perform a recursive calculation of data which necessitates the calculation of a data set based on another data set. For example, a calculation of data bⱼ[i] may be performed where i and j are indices, i varying from 0 to n and j from 0 to m, m and n being non-zero integers. This is notably the case in a calculation of a power matrix.

FIG. 1 represents an example of data to be calculated by such a processing system. In this example the integer m has the value 9 and the integer n the value 4. Five data sets are calculated, b₀[0] to b₉[0], b₀[1] to b₉[1], b₀[2] to b₉[2], b₀[3] to b₉[3], and b₀[4] to b₉[4]. The processing system calculates the data b₀[1] to b₉[0] respectively, then b₀[1] to b₉[1] and so on. A data set depends on the preceding data set. For example, b₀[1] is a function of b₀[0] via a function f:
b₀[1]=f(b₀[0]).
Similarly, b₁[1]=f(b₁[0]), b₂ [1]=f(b₂[0]) and so on. In a general way:
bⱼ[i+1]=f(bⱼ[i]).

FIG. 2 illustrates a circuit which permits to perform such a calculation. Such a circuit comprises a memory 21, a controller 22 and a calculation device 23. The example hereinafter describes the calculation of a second data set b₀[2] to b₉[2] based on a first data set b₀[1] to b₉[1]. In this example the calculation of a data by the calculation device 23 requires one clock cycle. The data of the first data set b₀[1] to b₉[1] are stored in the memory 21. During a clock cycle the data b₀[1] is sent to the calculation device 23 which then calculates the data b₀[2]. This data is then stored in the memory 21. With the next clock cycle the data b₁[1] is sent to the calculation device 23 which then calculates the data b₁[2]. This data is then stored in the memory 21. The circuit similarly proceeds for the calculation of the data b₂[2] to b₉[2].

The controller 22 controls the sending of a data of the first data set to the calculation device 23 for the calculation of a data of the second data set. In order to do this, the controller 22 generates an address from the memory 21 at which said data of the first data set is stored. The memory 21 is a RAM memory (RAM=Random Access Memory). When the memory 21 receives an address from the controller 22, it sends the data stored at this address to the calculation device 23.

Such a circuit thus requires a random access memory and a controller. Such a memory and such a controller cover a considerable silicon surface and take up a considerable amount of current. This is a drawback, notably in portable electronic devices such as a mobile telephone. Actually, in a portable electronic device the available silicon surface is limited. Moreover, as such a device is fed by a battery, a low current consumption is important in order to avoid too frequent a recharging of said battery.

### SUMMARY OF THE INVENTION

It is an object of the invention to propose a circuit for calculating a second data set based on a first data set, said circuit occupying a reduced silicon surface and presenting a reduced current consumption.

A circuit according to the invention and as defined in the opening paragraph is characterized in that it comprises transport means for routing a data of the first data set from the output to the input of the calculation device, in a number of clock cycles depending on the number of data of the first data set and of the predefined number of cycles necessary for the calculation of a data, a data advancing through said transport means with each clock cycle.

When a data of the first data set is calculated by a calculation device and is to be used by this calculation device several clock cycles later for calculating a data of the second data set, the data of the first data set is routed to the input of the calculation device by transport means, controlled solely by said clock. The transport means are such that the data of the first data set reaches at the input of the calculation device at the moment when it is to be used by said calculation device. Thus the circuit does not need to have a random access memory nor a controller which permits to reduce the consumption of such a circuit as well as the silicon surface covered by such a circuit.

Advantageously, the transport means comprise regulation means for regulating the number of cycles necessary for routing a data from the output to the input of said calculation device. Such a circuit has then a large flexibility. In fact, the data sets to be processed by the circuit may have a variable number of data. The number of cycles necessary for routing a data from the output to the input of the calculation device depends, inter alia, on the number of data of the data sets. Thanks to the regulation means it is possible to regulate the number of cycles necessary for routing a data from the output to the input of the calculation device as a function of the number of data of the data sets to be processed. Thus, such a circuit may be used for processing data sets which have different numbers of data.

In a preferred embodiment the transport means comprise at least a clock-activated register, said register being capable of storing a new data with each clock cycle. According to this embodiment the transport means comprise solely registers capable of storing one data. Such registers cover little silicon surface and have low current consumption. Such a circuit is furthermore easy to design, the number of such registers corresponding to the number of cycles necessary for routing a data from the output to the input of the calculation device.

### BRIEF DESCRIPTION OF THE DRAWINGS

These and other aspects of the invention are apparent from and will be elucidated, by way of non-limitative example, with reference to the embodiment(s) described hereinafter.

In the drawings:

FIG. 1 illustrates an example of data to be calculated;

FIG. 2 is a block diagram illustrating a prior-art circuit for the calculation of the data of FIG. 1;

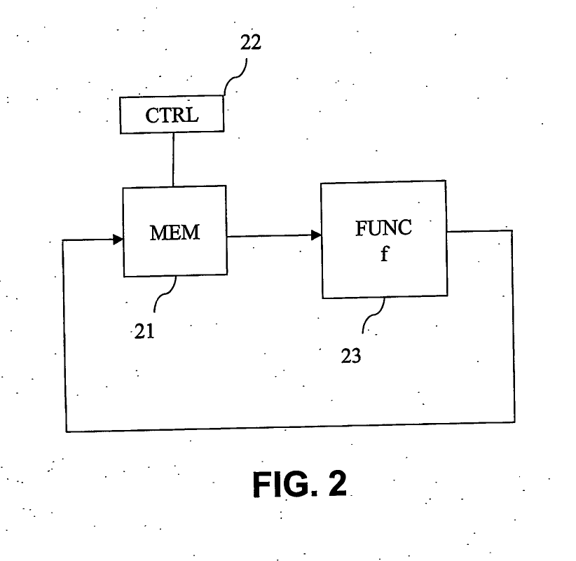

FIG. 3 is a block diagram illustrating a circuit according to the invention;

FIG. 4 is a block diagram illustrating a circuit in accordance with an advantageous embodiment of the invention;

FIG. 5 illustrates a circuit in accordance with the invention for the calculation of multiplication accumulations;

FIG. 6 illustrates a communication network comprising a circuit in accordance with the invention;

FIG. 7 illustrates a calculation of an interleaving matrix and of an interleaved block;

FIG. 8 illustrates a circuit in accordance with the invention for the calculation of intracolumn permutation elements of an interleaver.

### DESCRIPTION OF PREFERRED EMBODIMENTS

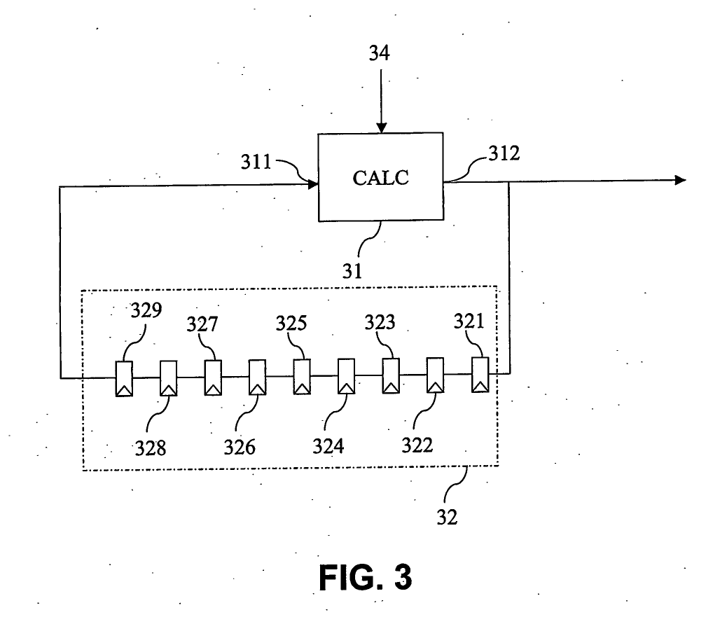

FIG. 3 illustrates an example of a circuit in accordance with the invention. Such a circuit comprises a calculation device 31 which has an input 311 and an output 312, as well as transport means 32. In this example the transport means comprise nine registers 321 to 329. The calculation device 31 may further receive additional data 34 such as coefficients.

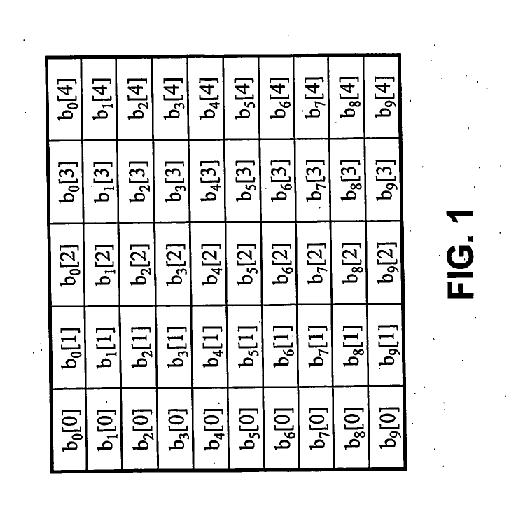

The example described hereinafter shows how a second data set is calculated based on a first data set by means of the circuit of FIG. 3. This example is applied to a second data set b₀[2] to b₉[2] and to the first data set b₀[1] to b₉[1] of FIG. 1.

Previously, the data of the first data set are calculated based on initial data corresponding to the data set b₀[0] to b₉[0] of FIG. 1. These data are sent in the form of additional data 34 to the calculation device 31. During a first clock cycle the data b₀[0] is sent to the calculation device 31. The data b₀[1] is then calculated by the calculation device 31 and stored in the register 321. It will be noted that the data b₀[1] may be stored in parallel in a storage device not shown in FIG. 1. During a second clock cycle the data b₁[0] is sent to the calculation device 31. The data b₁[1] is then calculated by the calculation device 31 and stored in the register 321 instead of the data b₀[1] which is sent to the register 322. Actually, the registers 321 to 329 are activated by the clock, that is to say, at each clock cycle the data present in a register leaves this register.

Similar operations are carried out for the calculation of the data b₂[1] to b₉[1]. During a tenth clock cycle the data b₁ [0], stored in the register 329, is sent to the input 311 of the calculation device 31, whereas the data b₉[1] is calculated by the calculation device 31 and sent to the register 321.

During an eleventh clock cycle the data b₀[2] of the second data set is calculated by the calculation device 31, based on the data b₀[1]. This data b₀[2] is then stored in the register 321. During this eleventh clock cycle the data b₁[1], stored in the register 329, is sent to the input 311 of the calculation device 31. During a twelfth clock cycle the data b₁[2] is calculated by the calculation device 31 and stored in the register 321. Similar operations are carried out for the calculation of the data b₂[2] to b₉[2].

In this example it is supposed that the calculation of a data by the calculation device 31 requires a single clock cycle. It is possible for such a calculation to require various clock cycles. For example, let us suppose that such a calculation requires three clock cycles.

During a first clock cycle the data b₀[0] is sent to the calculation device 31. During a second clock cycle the data b₁[0] is sent to the calculation device 31. During a third clock cycle the data b₂[0] is sent to the calculation device 31. During this third clock cycle the data b₀[1] is calculated, since the calculation of a data necessitates three clock cycles. This data is then stored in the register 321. During a tenth clock cycle the data b₉[0] is sent to the calculation device 31. The data b₀[1] is then situated in the register 327 and is to be sent to the calculation device 31 so as to initiate the calculation of the data b₀[2] of the second data set. Consequently, the transport means 32 require only seven registers 321 to 327.

As a result, the number of clock cycles necessary for routing a data from the output to the input of the calculation device 31 depends both on the number of data of the data sets and on the number of clock cycles necessary for the calculation of one data. In a general way, if the data sets comprise k data and if the number of clock cycles required for the calculation of one data has the value 1, the number of clock cycles necessary for the routing of one data from the output to the input of the calculation device 31 has the value (k−1). In the example of FIG. 3 this means that the transport means require (k−1) registers activated by the clock.

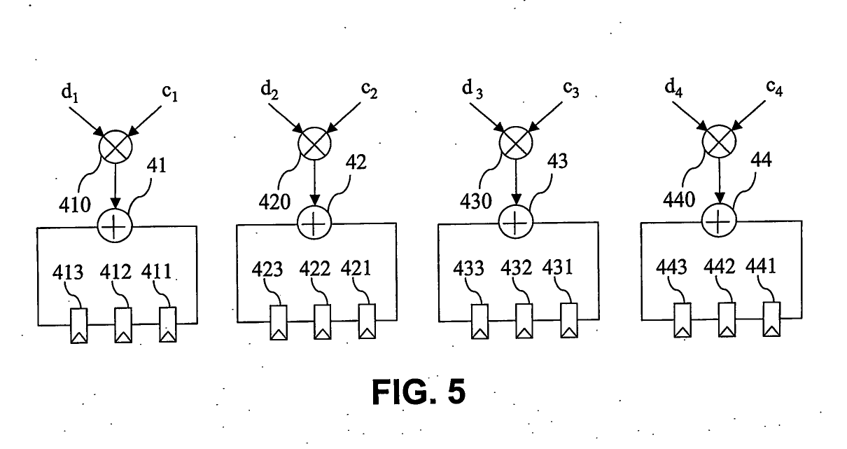

In the preceding examples it was supposed, inter alia, that the calculations are pipelined, that is to say that with each clock cycle one data is sent to the calculation device 31. It is possible that a data is not sent to the calculation device 31 with each clock cycle, notably when the circuit in accordance with the invention comprises various calculation devices. In such a case the number of clock cycles necessary for routing a data from the output to the input of a calculation device also depends on the number of data of the data sets and on the number of clock cycles necessary for the calculation of one data, as is discussed in more detail with respect to FIG. 5.

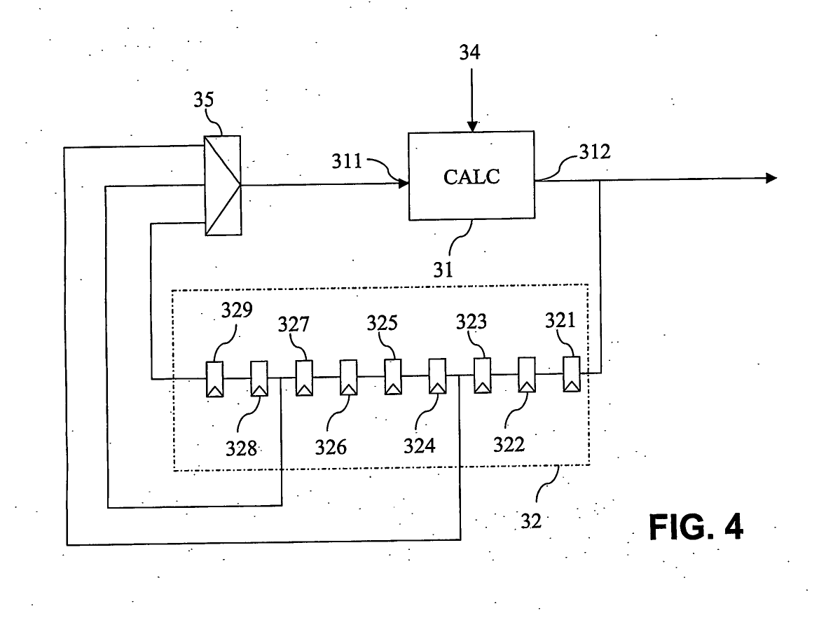

FIG. 4 illustrates a circuit according to an advantageous embodiment of the invention. Such a circuit comprises, in addition to the elements mentioned with respect to FIG. 3, regulation means for regulating the number of cycles necessary for routing a data from the output to the input of the calculation device 31, in the form of a multiplexer 35. The multiplexer 35, controlled by a control circuit not shown in FIG. 4, permits to send to the input 311 of the calculation device 31 the data stored either in the register 323 or in the register 327 or in the register 329. Thus, it is possible to regulate the number of cycles necessary for conveying a data from the output to the input of the calculation device 31. Actually, if the data stored in the register 323 is selected to be sent to the input of the calculation device 31, the number of cycles necessary for the routing of a data from the output to the input of the calculation 31 has the value 3. If the data stored in the register 327 is selected to be sent to the input of the calculation device 31, the number of cycles necessary for routing a data from the output to the input of the calculation device 31 has the value 7.

Consequently, such a circuit may be used for processing data sets which have diverse numbers of data. For example, for processing data sets comprising four data, while supposing that the calculations are pipelined and that the calculation of one data by the calculation device 31 requires one clock cycle, the data stored in the register 323 is selected to be sent to the input 311 of the calculation device 31. For processing data sets comprising eight data, the data stored in the register 327 is selected. For processing data sets comprising ten data, the data stored in the register 329 is selected.

Obviously, the regulation means may be designed in a way so as to permit the selection of a data from each of the registers 321 to 329. Thus it is possible to process data sets comprising a number of data between 2 and 10 in the case where the calculation of a data by the calculation device 31 needs one clock cycle.

FIG. 5 represents a circuit in accordance with the invention for the multiplication-accumulation calculation. Such a circuit comprises four calculation devices 41 to 44. These calculation devices are adders. With each calculation device 41 to 44 is associated a multiplier, 410 to 440 respectively. With each calculation device are also associated three registers, 411 to 413, 421 to 423, 431 to 433 and 441 to 443, respectively.

The circuit of FIG. 5 is intended for a calculation of four results of multiplication-accumulation MAC1 to MAC4, based on sixteen data d₁ to d₁₆ and sixteen coefficients c₁ to c₁₆:
MAC1=c₁*d₁+c₅*d₅+c₉*d₉+c₁₃*d₁₃
MAC2=c₂*d₂+c₆*d₆+c₁₀*d₁₀+c₁₄*d₁₄
MAC3=c₃*d₃+c₇*d₇+c₁₁*d₁₁+c₁₅*d₁₅
MAC4=c₄*d₄+c₈*d₈+c₁₂*d₁₂+c₁₆*d₁₆

Such a circuit is used, for example, in a decoding filter for data transmitted in the MP3 format. The data are transmitted in the form of data bands, each band being divided into sub-bands. The circuit of FIG. 5 is controlled by a clock. With each clock cycle a data reaches the circuit and is sent to one of the multipliers 410 to 440. The data d₁ is sent to the multiplier 410, the data d₂ to the multiplier 420, the data d₃ to the multiplier 430, the data d₄ to the multiplier 440, the data d₅ to the multiplier 410 and so on.

During a first clock cycle the coefficient c₁ is sent to the multiplier 410, the data c₁*d₁ is calculated and then a zero value is added thereto by the calculation device 41. The data c₁*d₁ is then sent to the register 411. During a second clock cycle the coefficient c₂ is sent to the multiplier 420, the data c₂*d₂ is calculated and then a zero value is added thereto by the calculation device 42. The data c₂*d₂ is then sent to the register 421. Similar operations are carried out for calculating the values c₃*d₃ and c₄*d₄ which are sent to the registers 431 and 441, respectively. The data c₁*d₁, c₂*d₂, c₃*d₃ and c₄*d₄ form a first data set.

During a fifth clock cycle the coefficient c5 is sent to the multiplier 410, the data c₅*d₅ is calculated and then the data c₁*d₁ is added thereto by the calculation device 41. Actually, during the fourth clock cycle the data c₁*d₁ which has advanced through the registers 411, 412 and 413 during second, third and fourth clock cycles, is sent to the calculation device 41. The data c₁*d₁+c₅*d₅ calculated by the calculation device 41 is then sent to the register 411. Similar operations are carried out during a sixth, a seventh and an eighth clock cycle for calculating the data c₂*d₂+c₆*d₆, c₃*d₃+c₇*d₇ and c₄*d₄+c₈*d₈. The data c₁*d₁+c₅*d₅, c₂*d₂+c₆*d₆, c₃*d₃+c₇*d₇ and c₄*d₄+c₈*d₈ form a second data set calculated on the basis of the first data set.

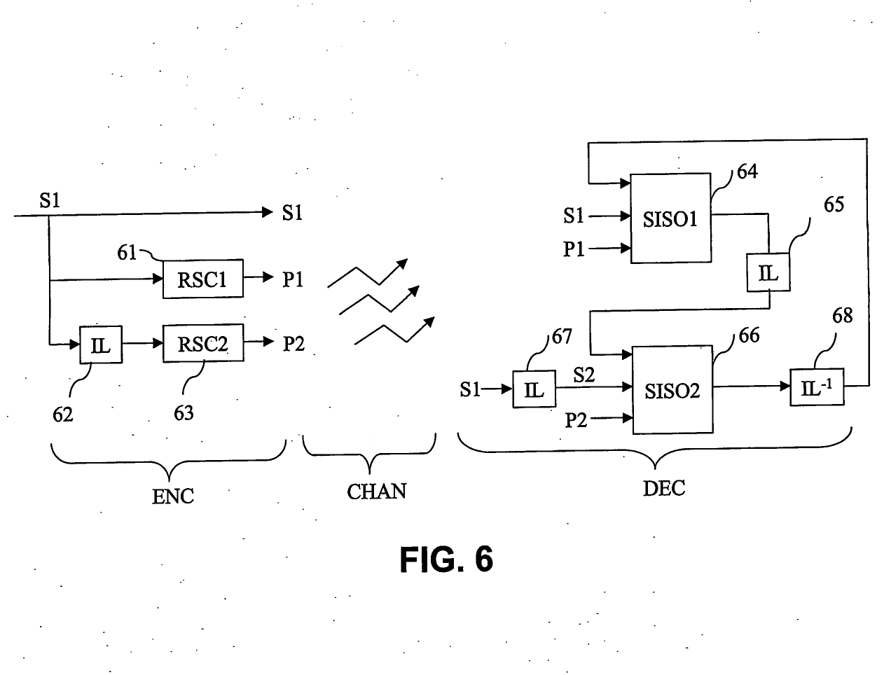

FIG. 6 illustrates a communication network comprising a circuit in accordance with the invention. Such a network comprises an encoding device ENC, a transmission channel CHAN and a decoding circuit DEC. At the level of the encoding device ENC, a data vector S1 to be transmitted is coded by a first systematic recursive coder 61, to produce a first parity vector P1. In parallel therewith, the data of the data vector S1 are interleaved by a first interleaver 62 and the vector resulting therefrom is coded by a second systematic recursive coder 63 to produce a second parity vector P2.

The interleaving of the data of a vector consists of permuting the components of this vector in a predefined order so as to obtain another vector. In the following there will be indifferently mention of the interleaving of data of a vector or the interleaving of the vector, so as to simplify the description.

Subsequently, the data vector S1, the first parity vector P1 and the second parity vector P2 are sent over the transmission channel CHAN to a receiver (not shown in FIG. 6). This is done by a transmitter (not shown in FIG. 6). The data vector S1, the first parity vector P1 and the second parity vector P2 are then sent to the decoding circuit DEC.

The decoding circuit DEC comprises a first decoder 64, a second decoder 66, a second interleaver 65, a third interleaver 67 and a de-interleaver 68. In the example of FIG. 1 the decoders 64 and 66 are soft-input-soft-output decoders. (SISO).

This decoding circuit DEC operates in iterative manner. During an iteration the first decoder 64 calculates a first extrinsic output data vector based on the data vector S1 received, the first parity vector P1 received and an extrinsic data vector coming from the second decoder 66. If there is not yet an extrinsic data vector coming from the second decoder 66, it is replaced by a predefined vector, for example a unit vector. This is possible during the first iteration of a decoding.

The first extrinsic output data vector is interleaved thanks to the second interleaver 65 and the vector resulting therefrom is sent to the second decoder 66. The second decoder 66 then calculates a second extrinsic output data vector based on the second parity vector P2, on a vector S2 coming from the third interleaver 67 which has for its input the data vector S1, and on the vector coming from the second interleaver 65. The second extrinsic output data vector is then de-interleaved by the de-interleaver 68 and the vector resulting therefrom is sent to the first decoder 64. A new iteration may then be performed.

Such a decoding circuit may be used in an electronic device, such as a third-generation mobile telephone.

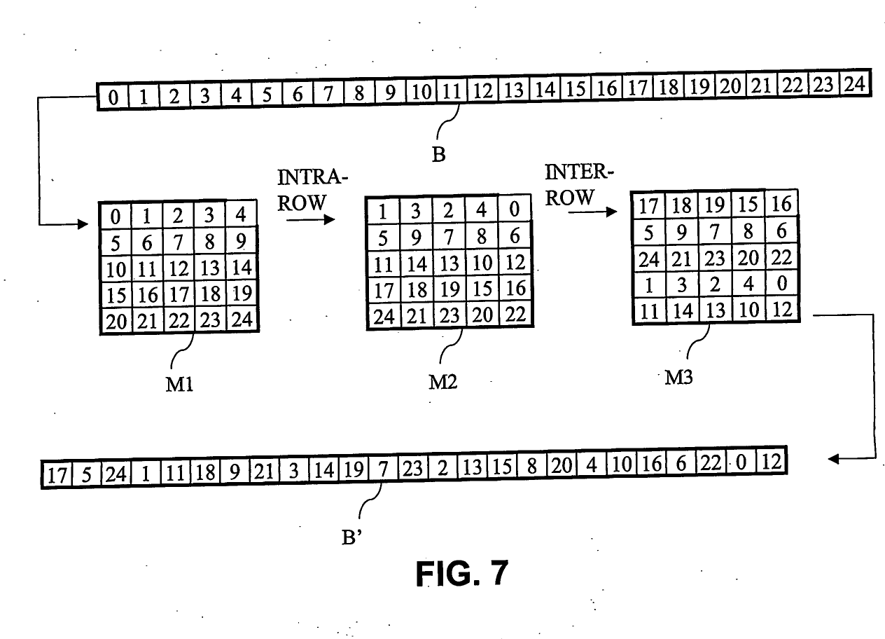

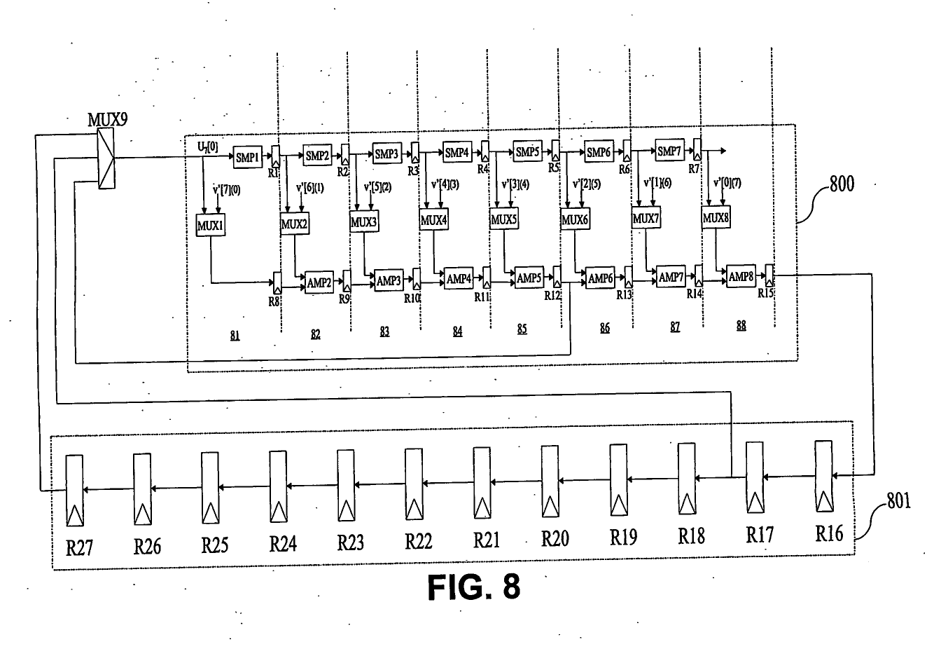

The interleaving of the data requires the calculation of intracolumn permutation elements as is described with reference to FIG. 7. Such a calculation of intracolumn permutation elements is carried out by a system comprising a circuit according to the invention as this is described with reference to FIG. 8.

FIG. 7 illustrates a calculation of an interleaving matrix and of an interleaved block, carried out by an interleaver of the communication network of FIG. 6. The example described hereinafter is applied to an interleaver according to the “3GGP TS 25.212 V3.9.0 (2002-03)” standard.

An object of such an interleaver is to permute the positions of the data comprised in a data vector containing K bits, K being an integer between 40 and 5114. The interleaver transforms the data vector into an interleaved data vector thanks to an interleaving scheme defined by an interleaving matrix containing R rows and C columns.

The example of FIG. 7 illustrates how the interleaving matrix is defined and how the bits of a data vector are interleaved. In this example a data vector B comprising 25 bits is interleaved and an interleaved data vector B′ is obtained. It will be noted that this example has for an object to show in a simple manner how an interleaved data vector B′ is obtained. More particularly, this example does not correspond to the “3GGP TS 25.212 V3.9.0 (2002-03)” standard, in which the length K of a data vector is between 40 and 5114.

In this example each bit of the data vector B is identified by an identifier between 0 and 24. The identifiers are written in a first matrix M1 row by row. Then, an intracolumn permutation is carried out in the matrix M1 according to an intracolumn permutation scheme, and a matrix M2 is obtained. An intercolumn permutation is then performed in the matrix M2 according to an intercolumn permutation scheme, and a matrix M3 is obtained. This matrix M3 is the interleaving matrix.

The identifiers of the bits of the interleaved data vector B′ are then obtained by a column-by-column reading of the identifiers of the interleaving matrix. In this example the bit identified by the identifier <<0>>, which is found in the first position in the data vector B, is located at the twenty-fourth position in the interleaved data vector B′. The bit identified by the identifier <<5>> in the data vector B is situated at the second position in the interleaved data vector B′, and so on.

For each value of K an interleaving scheme is defined. In order to make this, an intracolumn permutation scheme and an intercolumn permutation scheme are defined. The standard mentioned above specifies four intercolumn permutation schemes defined in the Table 1. For example, the intercolumn permutation scheme identified by number 1 replaces the first row of the matrix M2 which is denoted <<0>>, with the twentieth row of the matrix M2 which is denoted <<19>>, the second row with the tenth row and so on.

TABLE 1
intercolumn permutation scheme

| Number of | |
|---|---|
| scheme | Intercolumn permutation scheme |
| 1 | [19 9 14 4 0 2 5 7 12 18 10 8 13 17 3 1 16 6 15 11] |
| 2 | [19 9 14 4 0 2 5 7 12 18 16 13 17 15 3 1 6 11 8 10] |
| 3 | [9 8 7 6 5 4 3 2 1 0] |
| 4 | [4 3 2 1 0] |

The number of rows of the interleaving matrix, as well as the inter column permutation scheme, depends on the length K of the data vector as is described in Table 2. This Table is stored in a memory and, knowing the length K, the interleaver determines the number R of rows of the interleaving matrix as well as the intercolumn permutation scheme to be used. Consequently, for interleaving a data vector that has a given length K, the interleaver need not calculate the number of rows of the interleaving matrix nor the intercolumn permutation scheme, because these parameters are predetermined.

Conversely, it is not possible to store the intracolumn permutation schemes for each possible number C of columns. Actually, the number C of columns may take any integer value between 2 and 256. Consequently, storing the intracolumn permutation schemes for each possible number C of columns requires too much memory capacity. Therefore, the intracolumn permutation scheme is calculated each time a data vector possessing a new length K is to be interleaved.

TABLE 2
intercolumn permutation schemes and R as a function of K

| K | Scheme number | R |
|---|---|---|
| 40 ≦ K ≦ 159 | 4 | 5 |
| 160 ≦ K ≦ 200 | 3 | 10 |
| 201 ≦ K ≦ 480 | 1 | 20 |
| 481 ≦ K ≦ 530 | 3 | 10 |
| 531 ≦ K ≦ 2280 | 1 | 20 |
| 2281 ≦ K ≦ 2480 | 2 | 20 |
| 2481 ≦ K ≦ 3160 | 1 | 20 |
| 3161 ≦ K ≦ 3210 | 2 | 20 |
| 3211 ≦ K ≦ 5114 | 1 | 20 |

In order to calculate the intracolumn permutation scheme for a given length K, the parameters described hereinafter are determined.

In the first place a prime number p is determined. This number p is the smallest prime number so that (p−1)−K/R≧0.

Then the number C of columns is determined. This number C is the smallest integer from the set of integers {(p−1), p, (p+1)} so that K≦R*C.

A primitive root v is then determined as a function of the prime number p, as is described in Table 3.

TABLE 3
primitive root v as a function of the prime number p

| p | v | p | V | p | v | p | V |
|---|---|---|---|---|---|---|---|
| 7 | 3 | 59 | 2 | 113 | 3 | 191 | 19 |
| 11 | 2 | 61 | 2 | 127 | 3 | 193 | 5 |
| 13 | 2 | 67 | 2 | 131 | 2 | 197 | 2 |
| 17 | 3 | 71 | 7 | 137 | 3 | 199 | 3 |
| 19 | 2 | 73 | 5 | 139 | 2 | 211 | 2 |
| 23 | 5 | 79 | 3 | 149 | 2 | 223 | 3 |
| 29 | 2 | 83 | 2 | 151 | 6 | 227 | 2 |
| 31 | 3 | 89 | 3 | 157 | 5 | 229 | 6 |
| 37 | 2 | 97 | 5 | 163 | 2 | 233 | 3 |
| 41 | 6 | 101 | 2 | 167 | 5 | 239 | 7 |
| 43 | 3 | 103 | 5 | 173 | 2 | 241 | 7 |
| 47 | 5 | 107 | 2 | 179 | 2 | 251 | 6 |
| 53 | 2 | 109 | 6 | 181 | 2 | 257 | 3 |

Subsequently, a sequence of minimal prime integers q is calculated. This sequence is composed of R values and is constricted as follows:
q[0]=1
for j>0, q[j] is the smallest prime number so that:
   the highest common divisor between q[j] and (p−1) is 1
   q[j]>6
   q[j]>q[j−1].

Then, a permuted sequence of minimal prime integers r is calculated by utilizing the intercolumn permutation scheme T:r[T[j]]=q[j].

A basic sequence s is then calculated. This sequence is composed of p−1 values and is constructed as follows:
s[0]=1
s[i]=(v*s[i−1])mod p, where “mod p” indicates that the multiplication is effected modulo-p.

Finally, an intracolumn permutation scheme is calculated for each column j. For a given column j, C intracolumn permutation elements Uⱼ are calculated in accordance with the calculation mode described below, given for C=p:
Uⱼ[i]=s[(i*r[j])mod(p−1)] for i=0, 1, . . . , p−2
Uⱼ[p−1]=0

It may be demonstrated that the expression Uⱼ[i]=s[(i*r[j])mod(p−1)] is equal to:

Uⱼ[i+1]=(v′[j]*Uⱼ[i])mod p, where v′[j] is a new primitive root equal to Actually:

The expression s[i]=(v*s[i−1])mod p is equal to the expression:
s[i]=(vⁱ*s[0])mod p=vⁱmod p.
Consequently, the expression Uⱼ[i]=s[(i*r[j])mod(p−1)] is equal to the expression

Uⱼ[i]=V^{(i*r[j]mod(p-1)}mod p.
If one writes a=v and i*r[j]=b:
a^{b}mod p=[a^{n(p-1)}][a^{bmod(p-1)}]mod p, where n is such that b=n(p−1)+bmod(p−1).

$$\begin{matrix}\text{-} thus {a}^{b} mod p = [ {a}^{n ( p - 1 )} mod p ] [ {a}^{bmod ( p - 1 )} ] mod p \\ = [ {( {a}^{( p - 1 )} )}^{n} mod p ] [ {a}^{bmod ( p - 1 )} ] mod p \\ = {[ {a}^{( p - 1 )} mod p ]}^{n} [ {a}^{bmod ( p - 1 )} ] mod p\end{matrix}$$
If p is a prime number and if the greatest common divisor between a and p is 1, then a^{(p-1)}mod p=1. In this example a=v and v is never equal to p, which implies that the greatest common divisor between a and p is 1. Thus
   [a^{(p-1)}mod p]=1. Consequently, a^{b}mod p=a^{bmod (p-1)}mod p
If a is replaced by v and b by i*r[j] in this expression, one obtains:
   v^{i*r[j]}mod p=v^{(i*r[j])mod(p-1)}mod p=Uⱼ[i]
This expression is equal to the expression: Uⱼ[i]=(v′[j])ⁱmod p, where v′[j]=v^{r[j]}
By applying this expression in a recursive fashion, one obtains:
   Uⱼ[i+1]=(v′[j]*Uⱼ[i])mod p

FIG. 8 illustrates a system comprising a circuit according to the invention for calculating the intracolumn permutation elements described above.

Such a system comprises a calculation device 800 and transport means 801. The calculation device comprises fifteen registers R1 to R15, seven modulo-p shift elements SMP1 to SMP7, eight multiplexers MUX1 to MUX8 and seven modulo-p adders AMP2 to AMP8. The transport means 801 comprise twelve registers R16 to R27. The system further comprises regulation means in the form of a multiplexer MUX9.

The calculation device 800 permits to perform a modulo-p multiplication between two data x and y which are smaller than p. Let us suppose that x and y are written in binary language in eight bits from the least significant to the most significant bit:

x=x(0)x(1)x(2)x(3)x(4)x(5)x(6)x(7)

y=y(0)y(1)y(2)y(3)y(4)y(5)y(6)y(7)

During a stage 81 the data x is sent to the modulo-p shift element SMP1. If the bit y(0) has the value 1, the value x is copied in the register R8 thanks to the multiplexer Mux1. If the bit y(0) has the value 0, the value 0 is copied in the register R8.

The modulo-p shift element shifts the data x to the left and compares the data obtained with p. This data obtained is written as:

x(1)x(2)x(3)x(4)x(5)x(6)x(7)0

If this data obtained is larger than p, a modulo-p operation is carried out with this obtained data and the result of this operation is written in the register R1. If the data obtained is smaller than p it is copied in the register R1.

During a stage 82 the data stored in the register R1 is sent to the modulo-p shift element SMP2 and the multiplexer MUX2. Each step requires a clock cycle for activating the registers. If the second bit y(1) has the value 1, the data stored in the register-R1 is sent to the modulo-p adder AMP2. If the second bit y(1) has the value 0, the value 0 is sent to the modulo-p adder AMP2. The data stored in the register R8′ is also sent to the modulo-p adder AMP2. The modulo-p adder AMP2 performs a modulo-p addition of its two input values and sends the result to the register R9.

Similar operations are carried out during the stages 83 to 88 and the result of the modulo-p multiplication between x and y is obtained at the output of the modulo-p adder AMP8.

The calculation of intracolumn permutation elements by the circuit of FIG. 8 is described hereinafter.

The new primitive roots v′[j] and the intracolumn permutation elements are written in eight bits if the number of rows R of the interleaving matrix has the value 10 or 20 and in five bits if R has the value 5.

Let us suppose that the new primitive roots v′[j] and the intracolumn permutation elements are written in eight bits. In that case a modulo-p multiplication between a new primitive root and an intracolumn permutation element requires 8 clock cycles.

To calculate the intracolumn permutation element U₀[1], the intracolumn permutation element U₀[0] is sent to the modulo-p shift element SMP1 and to the multiplexer MUX1 during stage 81. After a first clock cycle the stage 82 is carried out during a second clock cycle. During this second clock cycle the intracolumn permutation element U₁[0] is sent to the modulo-p shifter SMP1 and to the multiplexer MUX1 in order to carry out the first modulo-p multiplication stage between v′[1] and U₁[0], whereas the second stage of the modulo-p multiplication between v′[0] and U₀[0] is carried out.

FIG. 8 illustrates the calculations carried out during an eighth clock cycle. The eighth stage of the modulo-p multiplication between v′[0] and U₀[0] is carried out in which the multiplexer MUX8 verifies whether the eighth bit v′[0](7) of the new primitive root v′[0] has the value 1. The seventh stage of the modulo-p multiplication between v′[1] and U₁[0] is carried out in which the multiplexer MUX7 verifies whether the seventh bit v′[1](6) of the new primitive root v′[1] has the value 1 and so on. The first stage of the modulo-p multiplication between v′[7] and U₇[0] is carried out in which the multiplexer MUX1 verifies whether the first bit v′[7](0) of the new primitive root v′[7] has the value 1.

At the end of the eighth clock cycle the intracolumn permutation element U₀[1] is calculated and stored in the register R15. Let us suppose that the interleaving matrix has 20 rows. For each column twenty intracolumn permutation elements are to be calculated. The intracolumn permutation elements U₀[1] to U₁₉[1] are thus calculated, then the element U₀[2] is calculated based on U₀[1], the element U₁[2] based on U₁[1] and so on. Consequently, each intracolumn permutation element calculated by the calculation device 800 is used again by this calculation device 800 twelve clock cycles after having been calculated. The transport means 801 which comprise twelve registers R16 to R27 permit to move one data from the output to the input of the calculation device 800 in twelve clock cycles.

Let us suppose that the interleaving matrix has 10 rows. For each column j ten intracolumn permutation elements are to be calculated. Consequently, each intracolumn permutation element calculated by the calculation device 800 is used again by this calculation device 800 two clock cycles after having been calculated. Thanks to the multiplexer MUX9 it is possible to select the data on the output, of the register R17 in order to transport them from the output to the input of the calculation device 800 in two clock cycles.

The verb “to comprise” and its conjugations are to be interpreted in a broad way, that is to say, as not excluding the presence of not only other elements than those listed after said verb, but also a plurality of elements already mentioned after said verb and preceded by the word “a” or “an”.

1. A circuit for calculating a second data set based on a first data set calculated by at least a calculation device (31) that is capable of calculating a data in a predefined number of clock cycles, said calculation device having an input (311) and an output (312), said circuit being characterized in that it comprises transport means (32) for routing a data of the first data set from the output to the input of the calculation device, in a number of clock: cycles depending on the number of data of the first data set and of the predefined number of cycles necessary for the calculation of a data, a data advancing through said transport means with each clock cycle.

2. A circuit as claimed in claim 1, characterized in that the transport means comprise regulation means (35) for regulating the number of cycles necessary for transporting a data from the output to the input of said calculation device.

3. A circuit as claimed in one of the claims 1 or 2, characterized in that the transport means comprise at least a clock-activated register (321), said register being capable of storing a new data with each clock cycle.

4. A system for calculating intracolumn permutation elements of an interleaver, said system comprising a circuit as claimed in claim 1.

5. A decoding circuit comprising a system as claimed in claim 4.

6. An electronic device comprising a decoding circuit as claimed in claim 5.

7. A communication network comprising at least a transmitter capable of sending signals, a transmission channel, a receiver capable of receiving said signals and a decoding circuit as claimed in claim 5.
